(19) United States
(12) Patent Application Publication
(10) Pub. No.: US 2025/0255137 A1
(43) Pub. Date: Aug. 7, 2025

(54) DISPLAY APPARATUS HAVING LIGHT-EMITTING DEVICES AND COLOR FILTERS

(71) Applicant: LG Display Co., Ltd., Seoul (KR)

(72) Inventors: Jae Hyun PARK, Paju-si (KR); You Yong JIN, Paju-si (KR); So Yeon KIM, Paju-si (KR)

(73) Assignee: LG Display Co., Ltd., Seoul (KR)

(21) Appl. No.: 18/960,821

(22) Filed: Nov. 26, 2024

(30) Foreign Application Priority Data
Feb. 6, 2024 (KR) 10-2024-0018026
Oct. 14, 2024 (KR) 10-2024-0139716

(51) Int. Cl. H10K 59/38; H10K 59/80

(52) U.S. Cl. CPC H10K 59/38; H10K 59/873; H10K 59/879

(57) ABSTRACT

A display apparatus can include light-emitting devices on emission areas of a device substrate, an optical insulating layer disposed on the light-emitting devices, and color filters disposed on the optical insulating layer. The optical insulating layer can include optical grooves overlapping with the emission areas. At least two of the color filters can be stacked on a sidewall of each optical groove. A bottom surface of each optical groove can be covered by one of the color filters. Thus, in the display apparatus, a color mixing and a reflection of external light can be prevented, and the quality of an image recognized a user can be improved.

### CROSS-REFERENCE TO RELATED APPLICATIONS

This application claims priority to Korean Patent Application Nos. 10-2024-0018026, filed on Feb. 6, 2024, and 10-2024-0139716, filed on Oct. 14, 2024, in the Republic of Korea, the entire contents of which are hereby expressly incorporated by reference into the present application.

### BACKGROUND OF THE DISCLOSURE

### Field

The present disclosure relates to a display apparatus in which a light-emitting device and a color filter are stacked on each emission area of a device substrate.

### Discussion of the Related Art

Generally, a display apparatus provides an image to a user. For example, the display apparatus can include light-emitting devices disposed on emission areas of a device substrate. Each of the light-emitting devices can emit light for displaying a specific color. For example, each of the light-emitting devices can include a first electrode, a light-emitting unit and a second electrode, which are sequentially stacked on one of the emission areas.

Each of the emission areas can display a different color from an adjacent emission area. For example, color filters can be disposed on the light-emitting devices. The color filter of each emission area can include a different material from the color filter of the adjacent emission area. For example, each of the color filters can be one of a blue color filter, a green color filter and a red color filter. A barrier pattern can be disposed between the color filters. The barrier pattern can include a material for blocking the light. Thus, in the display apparatus, the color mixing can be prevented by the barrier pattern.

In the display apparatus, some of the light can be reflected by the barrier pattern. For example, in the display apparatus, external light can be reflected toward the user by the barrier pattern. Further, in the display apparatus, the light emitted from the light-emitting device of each emission area can be reflected toward the adjacent emission area by the barrier pattern. Thus, in the display apparatus, the light passing through the color filer of an unintended emission area can be provided to the user by the barrier pattern. As such, in the display apparatus, the quality of the image recognized by the user can be decreased.

### SUMMARY OF THE DISCLOSURE

Accordingly, the present disclosure is directed to a display apparatus that substantially obviates one or more problems due to limitations and disadvantages of the related art.

An object of the present disclosure is to provide a display apparatus capable of improving the quality of the image recognized by a user.

Another object of the present disclosure is to provide a display apparatus capable of preventing the reflection of the external light and the light leakage.

Additional advantages, objects, and features of the disclosure will be set forth in part in the description which follows and in part will become apparent to those having ordinary skill in the art upon examination of the following or can be learned from practice of the disclosure. The objectives and other advantages of the disclosure can be realized and attained by the structure particularly pointed out in the written description and claims hereof as well as the appended drawings.

To achieve these objects and other advantages and in accordance with the purpose of the present disclosure, as embodied and broadly described herein, there is provided a display apparatus comprising a device substrate. A first light-emitting device is disposed on a first emission area of the device substrate. An optical insulating layer is disposed on the first light-emitting device. The optical insulating layer includes a first optical groove. The first optical groove overlaps the first emission area. A first color filer is disposed on a first bottom surface of the first optical groove. The first color filter extends onto a first sidewall of the first optical groove. A second color filter overlaps the first color filter on the first sidewall. The second color filter includes a different material from the first color filter. The first bottom surface includes a region that does not overlap with the second color filter.

According to aspects of the present disclosure, the light passing through the second color filer can display a different color from the light passing through the first color filter.

According to aspects of the present disclosure, the first bottom surface of the first optical groove can have a greater size than the first emission area.

According to aspects of the present disclosure, a pixel lens can be disposed on the optical insulating layer. The pixel lens can overlap the first emission area. The pixel lens can include a region disposed inside the first optical groove.

According to aspects of the present disclosure, a second light-emitting device can be disposed between a second emission area of the device substrate and the optical insulating layer. The optical insulating layer can include a second optical groove overlapping with the second emission area. The second optical groove can be spaced apart from the first optical groove. The first color filer and the second color filter can be stacked on a second sidewall of the second optical groove. A second bottom surface of the second optical groove can include a region that does not overlap with the first color filter.

According to aspects of the present disclosure, the second color filter can extend onto the second bottom surface of the second optical groove.

According to aspects of the present disclosure, the first color filter and the second color filter can extend onto an upper surface of the optical insulating layer opposite to the device substrate.

According to aspects of the present disclosure, an upper barrier pattern can be disposed on the upper surface of the optical insulating layer. The upper barrier pattern can be covered by the first color filter and the second color filter.

According to aspects of the present disclosure, an align key can be disposed between the device substrate and the optical insulating layer. The align key can be spaced apart from the first emission area. At least one of the first color filter and the second color filter can include an opening corresponding to the align key.

According to aspects of the present disclosure, an encapsulation structure can be disposed between the first light-emitting device and the optical insulating layer. The optical insulating layer can include a region disposed between the encapsulation structure and the first bottom surface of the first optical groove.

In another embodiment of the present disclosure, there is provided a display apparatus comprising a device substrate. Light-emitting devices and an encapsulation structure are disposed on the device substrate. The light-emitting devices are disposed on emission areas of the device substrate. The light-emitting devices are covered by the encapsulation structure. An optical insulating layer is disposed on the encapsulation structure. The optical insulating layer includes optical grooves. Each of the optical grooves exposes a portion of the encapsulation structure overlapping with one of the emission areas. Color filters are stacked on the optical insulating layer. The color filters extend onto a sidewall of each optical groove. The light emitted from each emission area displays a different color from the light emitted from adjacent emission area. A center area of a bottom surface of each optical groove is covered by one of the color filters.

According to aspects of the present disclosure, the color filter disposed on the center area of the bottom surface of each optical groove can include a different material from the color filter disposed on the center area of the bottom surface of adjacent optical groove.

According to aspects of the present disclosure, an align key can be disposed between the device substrate and the encapsulation structure. The align key can be spaced apart from the emission areas. The optical insulating layer can include an align groove overlapping with the align key. The align groove can be spaced apart from the optical grooves. At least two of the color filters can extend onto a sidewall of the align groove.

According to aspects of the present disclosure, at least portion of a bottom surface of the align groove can be exposed by the color filters.

According to aspects of the present disclosure, the device substrate can include an active area in which the emission areas are disposed and a bezel area disposed outside the active area. The align key can be disposed between the bezel area of the device substrate and the encapsulation structure.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a view schematically showing a display apparatus according to an embodiment of the present disclosure;

FIG. 2 is a view showing a circuit of a pixel area in the display apparatus according to the embodiment of the present disclosure;

FIG. 3 is a view showing a cross-section of the pixel areas in the display apparatus according to the embodiment of the present disclosure;

FIG. 4 is a graph showing a relative luminance of a comparative display apparatus that does not include optical grooves and the display apparatus according to the embodiment of the present disclosure;

FIG. 5 is an enlarged view of an align area in FIG. 1;

FIG. 6 is a view taken along line I-I′ of FIG. 5; and

FIGS. 7 to 25 are views showing a display apparatus according to another embodiment of the present disclosure.

### DETAILED DESCRIPTION OF THE EMBODIMENTS

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure can be embodied in other forms and is not limited to the embodiments described below. Further, the term “can” fully encompasses all the meanings and coverages of the term “may.”

In addition, the same or extremely similar elements can be designated by the same reference numerals throughout the disclosure and in the drawings, the lengths and thickness of layers and regions can be exaggerated for convenience. It will be understood that, when a first element is referred to as being “on” a second element, although the first element can be disposed on the second element so as to come into contact with the second element, a third element can be interposed between the first element and the second element.

Here, terms such as, for example, “first” and “second” can be used to distinguish any one element with another element and may not define order or sequence. However, the first element and the second element can be arbitrary named according to the convenience of those skilled in the art without departing the technical sprit of the present disclosure.

The terms used in the disclosure of the present disclosure are merely used in order to describe particular embodiments, and are not intended to limit the scope of the present disclosure. For example, an element described in the singular form is intended to include a plurality of elements unless the context clearly indicates otherwise. In addition, in the disclosure of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

Further, unless ‘directly’ is used, the terms “connected” and “coupled” can include that two components are “connected” or “coupled” through one or more other components located between the two components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

A display apparatus according to various embodiments of the present disclosure will now be discussed referring to the drawings. All the components of each display apparatus according to all embodiments of the present disclosure are operatively coupled and configured.

### Embodiments

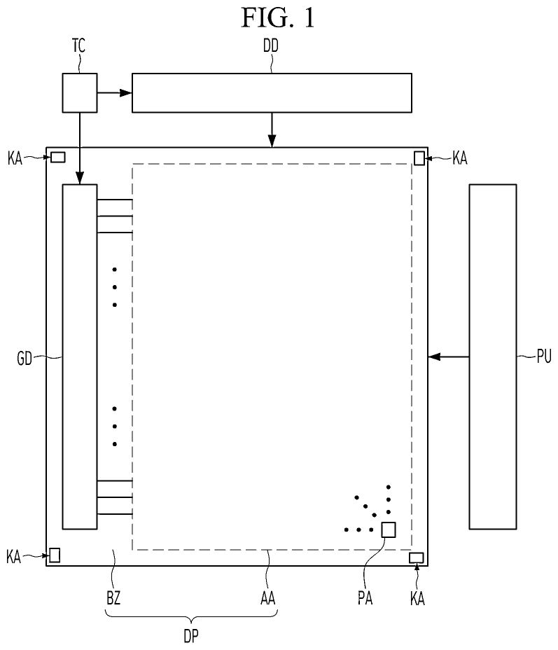

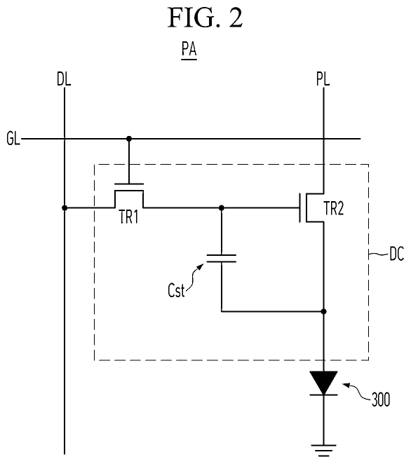

FIG. 1 is a view schematically showing a display apparatus according to an embodiment of the present disclosure. FIG. 2 is a view showing a circuit of a pixel area in the display apparatus according to the embodiment of the present disclosure.

Referring to FIGS. 1 and 2, the display apparatus according to the embodiment of the present disclosure can include a display panel DP. The display panel DP can generate an image provided to a user. For example, a plurality of pixel areas PA can be disposed within the display panel DP. Various signals can be provided in each pixel area PA through signal wirings GL, DL and PL. The signal wirings GL, DL and PL can include gate lines GL applying a gate signal, data lines DL applying a data signal, and power voltage supply lines PL supplying a power voltage. Each of the pixel areas PA can display a specific color according to the signal applied through the signal wirings GL, DL and PL. For example, a light-emitting device 300 and a driving circuit DC electrically connected to the light-emitting device 300 can be disposed in each pixel area PA.

The driving circuit DC can control the light-emitting device 300 according to a signal applied to the signal wirings GL, DL and PL. For example, the driving circuit DC can supply a driving current corresponding to the data signal to the light-emitting device 300 according to the gate signal. The driving current supplied by the driving circuit DC can be maintained for one frame. For example, the driving circuit DC can include a first thin film transistor TR1, a second thin film transistor TR2 and a storage capacitor Cst.

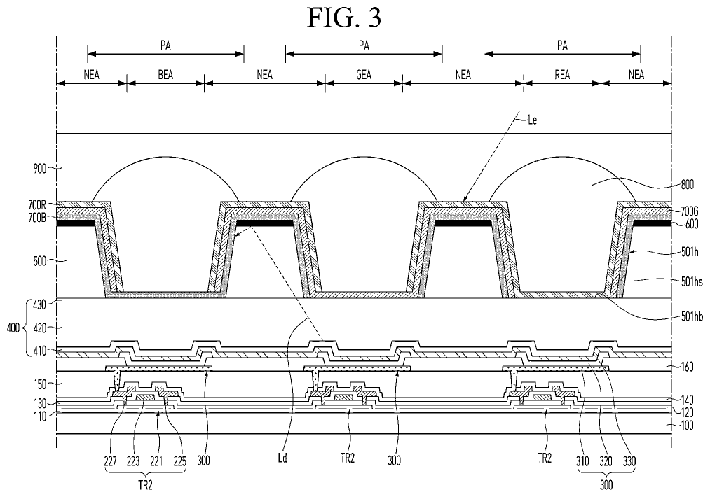

FIG. 3 is a view showing a cross-section of the pixel areas in the display apparatus according to the embodiment of the present disclosure;

Referring to FIGS. 2 and 3, the first thin film transistor TR1 can transmit the data signal to the second thin film transistor TR2 according to the gate signal. For example, the first thin film transistor TR1 can function as a switching thin film transistor. The first thin film transistor TR1 can include a first semiconductor pattern, a first gate electrode, a first drain electrode and a first source electrode. For example, the first gate electrode can be electrically connected to the gate line GL, and the first drain electrode can be electrically connected to the date line DL.

The second thin film transistor TR2 can generate the driving current corresponding to the data signal. For example, the second thin film transistor TR2 can function as a driving thin film transistor. The second thin film transistor TR2 can include a second semiconductor pattern 221, a second gate electrode 223, a second drain electrode 225 and a second source electrode 227. For example, the second gate electrode 223 can be electrically connected to the first source electrode, and the second drain electrode 225 can be electrically connected to the power voltage supply line PL.

The second semiconductor pattern 221 can include a semiconductor material. For example, the second semiconductor pattern 221 can include Low-Temperature Polycrystalline Silicon (LTPS) or an oxide semiconductor, such as IGZO. The second semiconductor pattern 221 can include a drain region, a channel region and a source region. The channel region can be disposed between the drain region and the source region. The drain region and the source region can have a smaller resistance than the channel region. For example, the drain region and the source region can include a conductive region of an oxide semiconductor. The channel region can be a region of an oxide semiconductor, which is not conductorized.

The second semiconductor pattern 221 can include a same material as the first semiconductor pattern. The second semiconductor pattern 221 can be disposed on a same layer as the first semiconductor pattern. The second semiconductor pattern 221 can be formed by a same process as the first semiconductor pattern. For example, the second semiconductor pattern 221 can be formed simultaneously with the first semiconductor pattern.

The second gate electrode 223 can be disposed on a portion of the second semiconductor pattern 221. For example, the second gate electrode 223 can overlap the channel region of the second semiconductor pattern 221. The drain region and the source region of the second semiconductor pattern 221 can be disposed outside the second gate electrode 223. The second gate electrode 223 can include a conductive material. For example, the second gate electrode 223 can include a metal, such as aluminum (Al), chrome (Cr), copper (Cu), molybdenum (Mo), titanium (Ti) and tungsten (W). The second gate electrode 223 can be spaced apart from the second semiconductor pattern 221. The second gate electrode 223 can be insulated from the second semiconductor pattern 221. For example, the channel region of the second semiconductor pattern 221 can have an electrical conductivity corresponding to a voltage of a signal applied to the second gate electrode 223.

The second gate electrode 223 can include a same material as the first gate electrode. The second gate electrode 223 can be disposed on a same layer as the first gate electrode. The second gate electrode 223 can be formed by a same process as the first gate electrode. For example, the second gate electrode 223 can be formed simultaneously with the first gate electrode.

The second drain electrode 225 can include a conductive material. For example, the second drain electrode 225 can include a metal, such as aluminum (Al), chrome (Cr), copper (Cu), molybdenum (Mo), titanium (Ti) and tungsten (W). The second drain electrode 225 can include a different material from the second gate electrode 223. For example, the second drain electrode 225 can be disposed on a different layer from the second gate electrode 223. The second drain electrode 225 can be electrically connected to the drain region of the second semiconductor pattern 221. The second drain electrode 225 can be insulated from the second gate electrode 223.

The second drain electrode 225 can include a same material as the first drain electrode. The second drain electrode 225 can be disposed a same layer as the first drain electrode. The second drain electrode 225 can be formed by a same process as the first drain electrode. For example, the second drain electrode 225 can be formed simultaneously with the first drain electrode.

The second source electrode 227 can include a conductive material. For example, the second source electrode 227 can include a metal, such as aluminum (Al), chrome (Cr), copper (Cu), molybdenum (Mo), titanium (Ti) and tungsten (W). The second source electrode 227 can include a different material from the second gate electrode 223. For example, the second source electrode 227 can be disposed on a different layer from the second gate electrode 223. The second source electrode 227 can be disposed on a same layer as the second drain electrode 225. The second source electrode 227 can include a same material as the second drain electrode 225. The second source electrode 227 can be formed by a same process as the second drain electrode 225. For example, the second source electrode 227 can be formed simultaneously with the second drain electrode 225. The second source electrode 227 can be electrically connected to the source region of the second semiconductor pattern 221. The second source electrode 227 can be spaced apart from the second drain electrode 225. The second source electrode 227 can be insulated from the second gate electrode 223.

The second source electrode 227 can include a same material as the first source electrode. The second source electrode 227 can be disposed a same layer as the first source electrode. The second source electrode 227 can be formed by a same process as the first source electrode. For example, the second source electrode 227 can be formed simultaneously with the first source electrode.

The storage capacitor Cst can maintain a voltage of a signal applied to the second gate electrode 223 of the second thin film transistor TR2 for one frame. For example, the storage capacitor Cst can be electrically connected to the second gate electrode 223 and the second source electrode 227 of the second thin film transistor TR2. The storage capacitor Cst can have a stacked structure of capacitor electrodes. For example, the storage capacitor Cst can have a structure in which a first capacitor electrode electrically connected to the second gate electrode 233 and a second capacitor electrode electrically connected to the second source electrode 227 are stacked. The storage capacitor Cst can be formed by using a process of forming the first thin film transistor TR1 and the second thin film transistor TR2. For example, the first capacitor electrode can be disposed on a same layer as the second gate electrode 223, and the second capacitor electrode can be disposed on a same layer as the second source electrode 227.

The driving circuit DC of each pixel area PA can be disposed on a device substrate 100. For example, the device substrate 100 can support the first thin film transistor TR1, the second thin film transistor TR2 and the storage capacitor Cst of each pixel area PA. The device substrate 100 can include an insulating material. For example, the device substrate 100 can include glass or plastic. A plurality of insulating layers 110, 120, 130, 140, 150 and 160 for preventing unnecessary electrical connection can be disposed on the device substrate 100. For example, a buffer insulating layer 110, a gate insulating layer 120, an interlayer insulating layer 130, a device passivation layer 140, a planarization layer 150 and a bank insulating layer 160 can be disposed on the device substrate 100.

The buffer insulating layer 110 can be disposed on the device substrate 100. The buffer insulating layer 110 can prevent the pollution due to the device substrate 100 in a process of forming the driving circuit DC of each pixel area PA. For example, an upper surface of the device substrate 100 toward the driving circuit DC of each pixel area PA can be covered by the buffer insulating layer 110. The first thin film transistor TR1, the second thin film transistor TR2 and the storage capacitor Cst of each pixel area PA can be disposed on the buffer insulating layer 110. The buffer insulating layer 110 can include an insulating material. For example, the buffer insulating layer 110 can be an inorganic insulating layer made of an inorganic insulating material, such as silicon oxide (SiOx) and silicon nitride (SiNx). The buffer insulating layer 110 can have a multi-layer structure. For example, the buffer insulating layer 110 can have a structure in which an inorganic insulating layer made of silicon oxide (SiOx) and an inorganic insulating layer made of silicon nitride (SiNx) are stacked.

The gate insulating layer 120 can be disposed on the buffer insulating layer 110. The second gate electrode 223 of each pixel area PA can be insulated from the second semiconductor pattern 221 of the corresponding pixel area PA by the gate insulating layer 120. For example, the gate insulating layer 120 can cover the first semiconductor pattern and the second semiconductor pattern 221 of each pixel area PA. The first gate electrode and the second gate electrode 223 of each pixel area PA can be disposed on the gate insulating layer 120. The gate insulating layer 120 can include an insulating material. For example, the gate insulating layer 120 can be an inorganic insulating layer made of an inorganic insulating material, such as silicon oxide (SiOx) and silicon nitride (SiNx).

The interlayer insulating layer 130 can be disposed on the gate insulating layer 120. The second drain electrode 225 and the second source electrode 227 of each pixel area PA can be insulated from the second gate electrode 223 of the corresponding pixel area PA by the interlayer insulating layer 130. For example, the interlayer insulating layer 130 can cover the first gate electrode and the second gate electrode 223 of each pixel area PA. The first drain electrode, the first source electrode, the second drain electrode 225 and the second source electrode 227 of each pixel area PA can be disposed on the interlayer insulating layer 130. The interlayer insulating layer 130 can include an insulating material. For example, the interlayer insulating layer 130 can be an inorganic insulating layer made of an inorganic insulating material.

The device passivation layer 140 can be disposed on the interlayer insulating layer 130. The device passivation layer 140 can prevent the damage of the driving circuit DC in each pixel area PA due to external moisture and impact. For example, the first drain electrode, the first source electrode, the second drain electrode 225 and the second source electrode 227 of each pixel area PA can be covered by the device passivation layer 140. The device passivation layer 140 can include an insulating material. For example, the device passivation layer 140 can be an inorganic insulating layer made of an inorganic insulating material.

The planarization layer 150 can be disposed on the device passivation layer 140. The planarization layer 150 can include an insulating material. The planarization layer 150 can include a different material from the device passivation layer 140. The planarization layer 150 can include a material having a relatively high fluidity. For example, the planarization layer 150 can be an organic insulating layer made of an organic insulating material. A thickness difference due to the driving circuit DC of each pixel area PA can be removed by the planarization layer 150. For example, an upper surface of the planarization layer 150 opposite to the device substrate 100 can be flat. The upper surface of the planarization layer 150 can be parallel to the upper surface of the device substrate 100. The planarization layer 150 can have a greater thickness than the buffer insulating layer 110, the gate insulating layer 120, the interlayer insulating layer 130 and the device passivation layer 140.

The light-emitting device 300 of each pixel area PA can be disposed on the upper surface of the planarization layer 150. The light-emitting device 300 of each pixel area PA can emit light displaying a specific color. For example, the light-emitting device 300 of each pixel area PA can include a first electrode 310, a light-emitting unit 320 and a second electrode 330, which are sequentially stacked on the planarization layer 150 of the corresponding pixel area PA.

The first electrode 310 and the second electrode 330 can include a conductive material. The second electrode 330 can include a different material from the first electrode 310. For example, the first electrode 310 can have a larger reflectance than the second electrode 330. A transmittance of the second electrode 330 can be larger than a transmittance of the first electrode 310. For example, the first electrode 310 can include a metal, and the second electrode 330 can be a transparent electrode made of a transparent conductive material, such as ITO and IZO. The second electrode 330 can have a work-function different from the first electrode 310. For example, a work-function of the second electrode 330 can be smaller than a work-function of the first electrode 310. Thus, in the display apparatus according to the embodiment of the present disclosure, the first electrode 310 can function as anode, and the second electrode 330 can function as cathode.

The light-emitting unit 320 can generate light having luminance corresponding to a voltage difference between the first electrode 310 and the second electrode 330. For example, the light-emitting unit 320 can include at least one emission material layer (EML). The emission material layer can include an organic emission material, an inorganic emission material, or a hybrid emission material. For example, the display apparatus according to the embodiment of the present disclosure can be an organic light-emitting display apparatus including an organic emission material. The light generated by the light-emitting unit 320 can be emitted outside through the second electrode 330.

The light-emitting unit 320 can have a multi-layer structure. For example, the light-emitting unit 320 can include at least one of a hole injection layer (HIL), a hole transport layer (HTL), an electron transport layer (ETL) and an electron injection layer (EIL). Thus, in the display apparatus according to the embodiment of the present disclosure, the efficiency of the light-emitting unit 320 can be improved.

The first electrode 310 of each pixel area PA can be electrically connected to the driving circuit DC of the corresponding pixel area PA. For example, the first electrode 310 of each pixel area PA can be in direct contact with the second source electrode 227 of the corresponding pixel area PA by penetrating the device passivation layer 140 and the planarization layer 150. Thus, in the display apparatus according to the embodiment of the present disclosure, the driving current generated by the driving circuit DC of each pixel area PA can be applied to the first electrode 310 of the corresponding pixel area PA.

The first electrode 310 of each pixel area PA can be insulated from the first electrode 310 of adjacent pixel area PA. For example, the first electrode 310 of each pixel area PA can be spaced apart from the first electrode 310 of adjacent pixel area PA. The bank insulating layer 160 can be disposed between the first electrodes 310 of adjacent pixel areas PA. The bank insulating layer 160 can include an insulating material. For example, the bank insulating layer 160 can be an organic insulating layer made of an organic insulating material. The bank insulating layer 160 can be disposed on the planarization layer 150. The bank insulating layer 160 can include a different material from the planarization layer 150.

The bank insulating layer 160 can partially expose the first electrode 310 of each pixel area PA. For example, an edge of the first electrode 310 in each pixel area PA can be covered by the bank insulating layer 160. The bank insulating layer 160 can define an emission area BEA, GEA and REA in each pixel area PA. For example, the light-emitting unit 320 and the second electrode 330 of each pixel area PA can be stacked on a portion of the corresponding first electrode 310 exposed by the bank insulating layer 160. The light-emitting unit 320 of each pixel area PA can be in direct contact with the first electrode 310 and the second electrode 330 of the corresponding pixel area PA within the emission area BEA, GEA and REA of the corresponding pixel area PA.

The first electrode 310 of each pixel area PA can be electrically connected to the second source electrode 227 of the corresponding pixel area PA at the outside of the emission area BEA, GEA and REA defined in the corresponding pixel area PA. For example, the connection area of the second source electrode 227 and the first electrode 310 in each pixel area PA can overlap the bank insulating layer 160. Thus, in the display apparatus according to the embodiment of the present disclosure, a portion of the first electrode 310 overlapping with the emission area BEA, GEA and REA of each pixel area PA can be in direct contact with the upper surface of the planarization layer 150. For example, in the display apparatus according to the embodiment of the present disclosure, the location change of the first electrode 310 in the emission area BEA, GEA and REA of each pixel area PA can be minimized. Therefore, in the display apparatus according to the embodiment of the present disclosure, the luminance deviation according to the generating location of the light emitted from the emission area BEA, GEA and REA of each pixel area PA can be prevented.

The emission area BEA, GEA and REA of each pixel area PA can display a different color from the emission area BEA, GEA and REA of adjacent pixel area PA. For example, the emission area BEA, GEA and REA of each pixel area PA can be one of a blue emission area BEA realizing blue color, a green emission area GEA realizing green color, and a red emission area REA realizing red color. The light emitted from the light-emitting device 300 of each pixel area PA can display a different color from the light emitted from the light-emitting device 300 of adjacent pixel area PA. For example, the light generated by the light-emitting unit 320 of each pixel area PA can be a blue light, a green light or a red light. The light-emitting unit 320 of each pixel area PA can be spaced apart from the light-emitting unit 320 of adjacent pixel area PA. For example, the light-emitting unit 320 of each pixel area PA can include an end disposed on the bank insulating layer 160.

A voltage applied to the second electrode 330 of each pixel area PA can be a same as a voltage applied to the second electrode 330 of adjacent pixel area PA. For example, the second electrode 330 of each pixel area PA can be electrically connected to the second electrode 330 of adjacent pixel area PA. The second electrode 330 of each pixel area PA can include a same material as the second electrode 330 of adjacent pixel area PA. The second electrode 330 of each pixel area PA can be in direct contact with the second electrode 330 of adjacent pixel area PA. For example, the second electrode 330 of each pixel area PA can be formed simultaneously with the second electrode 330 of adjacent pixel area PA. Thus, in the display apparatus according to the embodiment of the present disclosure, a process of forming the second electrode 330 in each pixel area PA can be simplified. And, in the display apparatus according to the embodiment of the present disclosure, the luminance of the light generated by the light-emitting unit 320 of each pixel area PA can be adjusted by the data signal applied to the driving circuit DC of the corresponding pixel area PA.

An encapsulation structure 400 can be disposed on the light-emitting device 300 of each pixel area PA. The encapsulation structure 400 can prevent the damage of the light-emitting devices 300 due to the external moisture and impact. The encapsulation structure 400 can have a multi-layer structure. For example, the encapsulation structure 400 can include a first encapsulating layer 410, a second encapsulating layer 420 and a third encapsulating layer 430, which are sequentially stacked on the second electrode 330 of each pixel area PA. The first encapsulating layer 410, the second encapsulating layer 420 and the third encapsulating layer 430 can include an insulating material. The second encapsulating layer 420 can include a different material from the first encapsulating layer 410 and the third encapsulating layer 430. For example, the first encapsulating layer 410 and the third encapsulating layer 430 can be an inorganic insulating layer made of an inorganic insulating material, and the second encapsulating layer 420 can be an organic insulating layer made of an organic insulating material. Thus, in the display apparatus according to the embodiment of the present disclosure, the damage of the light-emitting devices 300 due to the external moisture and impact can be effectively prevented. A thickness difference due to the light-emitting device 300 of each pixel area PA can be removed by the second encapsulating layer 420. For example, an upper surface of the encapsulation structure 400 opposite to the device substrate 100 can be flat. The upper surface of the encapsulation structure 400 can be parallel to the upper surface of the device substrate 100. The second encapsulating layer 420 can have a greater thickness than the first encapsulating layer 410 and the third encapsulating layer 430.

An optical insulating layer 500 can be disposed on the encapsulation structure 400. The optical insulating layer 500 can include an insulating material. The optical insulating layer 500 can include a transparent material. For example, the optical insulating layer 500 can include an inorganic insulating material and/or an organic insulating material. The optical insulating layer 500 can include a plurality of optical grooves 501h. Each of the optical grooves 501h can include an optical bottom surface 501hb and an optical sidewall 501hs. The optical bottom surface 501hb of each optical groove 501h can be disposed close to the encapsulation structure 400. Each of the optical groove 501h can completely penetrate the optical insulating layer 500. For example, the optical bottom surface 501hb of each optical groove 501h can be continuous with a lower surface of the optical insulating layer 500 toward the encapsulation structure 400. The optical sidewall 510hs of each optical groove 501h can extend from an edge of the optical bottom surface 501hb of the corresponding optical groove 501h. The optical sidewall 501hs of each optical groove 501h can be inclined with respect to the optical bottom surface 501hb of the corresponding optical groove 501h. For example, a horizontal width of each optical groove 501h can increase toward an upper surface of the optical insulating layer 500 opposite to the device substrate 100.

The optical grooves 501h can be disposed on the emission areas BEA, GEA and REA of the pixel areas PA. For example, the emission area BEA, GEA and REA of each pixel area PA can overlap one of the optical grooves 501h. A portion of the encapsulation structure 400 overlapping with the emission area BEA, GEA and REA of each pixel area PA can be exposed by the optical bottom surface 501hb of one of the optical grooves 501h. The optical bottom surface 501hb of the optical groove 501h in each pixel area PA can have a greater size than the emission area BEA, GEA and REA defined in the corresponding pixel area PA. Thus, in the display apparatus according to the embodiment of the present disclosure, the optical insulating layer 500 can't overlap the emission area BEA, GEA and REA of each pixel area PA. For example, in the display apparatus according to the embodiment of the present disclosure, a region disposed between the emission areas BEA, GEA and REA can define as a non-emission area NEA, and the optical insulating layer 500 can be disposed in the non-emission area NEA.

A barrier structure 600 can be disposed on the upper surface of the optical insulating layer 500. The barrier pattern 600 can be disposed outside the optical grooves 501h. For example, the optical bottom surface 501hb and the optical sidewall 510hs of each optical groove 501h can't be covered by the barrier pattern 600. The barrier pattern 600 can include a material blocking light. For example, the barrier pattern 600 can include a black dye, such as carbon black. Thus, in the display apparatus according to the embodiment of the present disclosure, the barrier pattern 600 can function as a black matrix. For example, in the display apparatus according to the embodiment of the present disclosure, the light emitted from the emission area BEA, GEA and REA of each pixel area PA toward the upper surface of the optical insulating layer 500 can be absorbed or reflected by the barrier pattern 600.

Color filters 700B, 700G and 700R can be stacked on the barrier pattern 600. The emission area BEA, GEA and REA of each pixel area PA can overlap one of the color filters 700B, 700G and 700R. For example, the color filters 700B, 700G and 700R can include a blue color filter 700B overlapping with the blue emission area BEA, a green color filter 700G overlapping with the green emission area GEA, and a red color filter 700R overlapping with the red emission area REA. Thus, in the display apparatus according to the embodiment of the present disclosure, the external light Le travelling toward the barrier pattern 600 can be blocked by the color filters 700B, 700G and 700R. For example, in the display apparatus according to the embodiment of the present disclosure, the external light Le that is not absorbed by the barrier pattern can't be reflected toward the user. Therefore, in the display apparatus according to the embodiment of the present disclosure, the deterioration in the quality of the image due to the reflection of the external light Le can be prevented.

The color filters 700B, 700G and 700R can extend onto the optical sidewall 501hs of each optical groove 501h. For example, the blue color filter 700B, the green color filter 700G and the red color filter 700R can be stacked on the optical sidewall 501hs of each optical groove 501h. The barrier pattern 600 can be covered by the color filters 700B, 700G and 700R. Thus, in the display apparatus according to the embodiment of the present disclosure, the light Ld that is emitted from the emission area BEA, GEA and REA of each pixel area PA and is not absorbed by the barrier pattern 600 can be blocked by the color filters 700B, 700G and 700R, which are stacked on the optical sidewall 501hs of each optical groove 501h. For example, in the display apparatus according to the embodiment of the present disclosure, the light reflected by the barrier pattern 600 can't proceed toward adjacent pixel area PA. Therefore, in the display apparatus according to the embodiment of the present disclosure, the unintentional mixing of the light can be effectively prevented.

In the display apparatus according to the embodiment of the present disclosure, the travelling direction of the light emitted from the emission area BEA, GEA and REA can be restricted by the barrier pattern 600, the optical grooves 501h and the color filters 700B, 700G and 700R. For example, in the display apparatus according to the embodiment of the present disclosure, the viewing angle of the light emitted from the emission area BEA, GEA and REA of each pixel area PA can be reduced by the barrier pattern 600, the optical grooves 501h and the color filters 700B, 700G and 700R. For example, in the display apparatus according to the embodiment of the present disclosure, a narrow viewing angle can be realized by the barrier pattern 600, the optical grooves 501h and the color filters 700B, 700G and 700R. Thus, in the display apparatus according to the embodiment of the present disclosure, a process of realizing the narrow viewing angle can be simplified. Therefore, in the display apparatus according to the embodiment of the present disclosure, the production energy can be reduced by process optimization.

Each of the color filters 700B, 700G and 700R can extend onto the optical bottom surface 501hb of one of the optical grooves 501h. The optical bottom surface 501hb of each optical groove 501h can be covered by one of the color filters 700B, 700G and 700R. For example, the optical bottom surface 501hb of the optical groove 501h overlapping with the blue emission area BEA can include a region that does not overlap with the green color filter 700G and the red color filter 700R, and the blue color filter 700B can be disposed on a portion of the optical bottom surface 501hb of the optical groove 501h exposed by the green color filter 700G and the red color filter 700R. The optical bottom surface 501hb of the optical groove 501h overlapping with the green emission area GEA can be in direct contact with the green color filter 700G, the blue color filter 700B and the red color filter 700R can't overlap a portion of the optical bottom surface 501hb of the optical groove 501h overlapping with the green color filter 700G. A center area of the optical bottom surface 501hb of the optical groove 501h exposed by the blue color filter 700B and the green color filter 700G can be covered by the red color filter 700R. Thus, in the display apparatus according to the embodiment of the present disclosure, the light generated by the light-emitting device 300 of the blue emission area BEA can be emitted outside passing through the blue color filer 700B, the light generated by the light-emitting device 300 of the green emission area GEA can be emitted outside passing through the green color filer 700G, and the light generated by the light-emitting device 300 of the red emission area REA can be emitted outside passing through the red color filer 700R. Therefore, in the display apparatus according to the embodiment of the present disclosure, the light leakage due to the light that does not pass through one of the color filters 700B, 700G and 700R can be prevented. And, in the display apparatus according to the embodiment of the present disclosure, the color reproduction can be improved.

A portion of the optical bottom surface 501hs of the optical groove 501h exposed by the green color filter 700G and the red color filter 700R can have a same size as the blue emission area BEA, a portion of the optical bottom surface 501hs of the optical groove 501h exposed by the blue color filter 700B and the red color filter 700R can have a same size as the green emission area GEA, and a portion of the optical bottom surface 501hs of the optical groove 501h exposed by the blue color filter 700B and the green color filter 700G can have a same size as the red emission area REA. Thus, in the display apparatus according to the embodiment of the present disclosure, the decrease in the quality of the image due to the light reflected by the barrier pattern 600 can be prevented, without reducing the area of the emission area BEA, GEA and REA defined in each pixel area PA.

Pixel lenses 800 can be disposed on the color filters 700B, 700G and 700R. The pixel lenses 800 can be disposed on the emission areas BEA, GEA and REA of the pixel areas PA. For example, the emission area BEA, GEA and REA of each pixel area PA can overlap one of the pixel lenses 800. The light passing through the optical bottom surface 501hb of each optical groove 501h and one of the color filters 700B, 700G and 700R can be concentrated by one of the pixel lenses 800. For example, each of the pixel lenses 800 can function as a convex lens. A surface of each pixel lenses 800 opposite to the optical insulating layer 500 can has a convex shape. Thus, in the display apparatus according to the embodiment of the present disclosure, a front luminance of the emission area BEA, GEA and REA defined in each pixel area PA can be improved.

The pixel lenses 800 can overlap the optical grooves 501h. For example, each of the pixel lenses 800 can include a region disposed inside one of the optical grooves 501h. The pixel lens 800 disposed on each pixel area PA can have a greater size than the emission area BEA, GEA and REA of the corresponding pixel area PA. For example, the optical groove 501h disposed on each pixel area PA can be filled by a portion of the pixel lens 800 disposed on the corresponding pixel area PA. Thus, in the display apparatus according to the embodiment of the present disclosure, the movement of the pixel lenses 800 due to the external impact can be prevented. And, in the display apparatus according to the embodiment of the present disclosure, the misalignment of the pixel lenses 800 in a forming process can be prevented. Therefore, in the display apparatus according to the embodiment of the present disclosure, the decrease in the quality of the image due to the position difference between the optical groove 501h and the pixel lens 800 on each pixel area PA can be prevented.

A lens passivation layer 900 can be disposed on the pixel lenses 800. The lens passivation layer 900 can prevent the damage of the pixel lenses 800 due to the external impact. For example, the surface of each pixel lens 800 having a convex shape can be completely covered by the lens passivation layer 900. The lens passivation layer 900 can include an insulating material. For example, the lens passivation layer 900 can include an inorganic insulating material and/or an organic insulating material. A refractive index of the lens passivation layer 900 can be smaller than a refractive index of each pixel lens 800. Thus, in the display apparatus according to the embodiment of the present disclosure, the light passing through the pixel lens 800 of each pixel area PA can't be reflected toward the device substrate 100 by the difference in the refractive index between the corresponding pixel lens 800 and the lens passivation layer 900. Therefore, in the display apparatus according to the embodiment of the present disclosure, the light extraction efficiency can be improved.

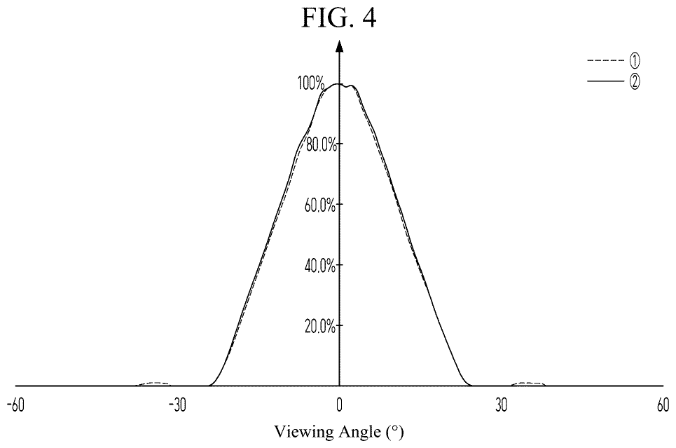

FIG. 4 is a graph showing a relative luminance of a comparative display apparatus \textcircled{1} that does not include optical grooves 501h and the display apparatus \textcircled{2} according to the embodiment of the present disclosure.

Referring to FIG. 4, the light leakage is detected at a point having a viewing angle of about 30° to 40° in the comparative display apparatus \textcircled{1}, but the light does not leak at points where the viewing angle is greater than 30° in the display device \textcircled{2} according to an embodiment of the present invention. For example, in the display apparatus according to the embodiment of the present disclosure, the light leakage can be prevented by the color filters 700B, 700G and 700R stacked on the optical sidewall 501hs of each optical groove 501h. Thus, in the display apparatus according to the embodiment of the present disclosure, the deterioration of the image due to the leaked light can be prevented. Therefore, in the display apparatus according to the embodiment of the present disclosure, the quality of the image recognized by the user can be improved.

Accordingly, the display apparatus according to the embodiment of the present disclosure can include the light-emitting devices 300, the optical insulating layer 500, the barrier pattern 600, the color filters 700B, 700G and 700R, the pixel lenses 800 and the lens passivation layer 900, which are disposed on the device substrate 100, wherein the optical insulating layer 500 can include the optical grooves 501h overlapping with the emission area BEA, GEA and REA, the optical bottom surface 501hb of each optical groove 501h can be covered by one of the color filters 700B, 700G and 700R, and the color filters 700B, 700G and 700R can be stacked on the optical sidewall 501hs of each optical groove 501h and the barrier pattern 600. Thus, in the display apparatus according to the embodiment of the present disclosure, the travelling direction of the light emitted from the light-emitting device 300 of each pixel area PA can be restricted by the barrier pattern 600 and the stacked structure of the color filter 700B, 700G and 700R, and the light that is not absorbed by the barrier pattern 600 and the light travelling toward the barrier pattern 600 can be blocked by the stacked color filter 700B, 700G and 700R. Therefore, in the display apparatus according to the embodiment of the present disclosure, the decrease in the quality of the image recognized by the user due to the light reflected by the barrier pattern 600 can be prevented.

And, in the display apparatus according to the embodiment of the present disclosure, the narrow viewing angle can be realized by the barrier pattern 600, the optical grooves 501h and the color filters 700B, 700G and 700R. For example, the image provided to the user can't be recognized by people around the user by the barrier pattern 600, the optical grooves 501h and the color filters 700B, 700G and 700R. For example, in the display apparatus according to the embodiment of the present disclosure, a process of realizing the narrow viewing angle can be simplified. Therefore, in the display apparatus according to the embodiment of the present disclosure, the production energy can be reduced by process optimization.

As shown in FIG. 1, the display panel DP can include an active area AA in which the pixel areas PA are disposed, and a bezel area BZ being disposed outside the active area AA. The bezel area BZ can be disposed outside the pixel areas PA. For example, the active area AA can be surrounded by the bezel area BZ. A gate driver GD electrically connected to the gate line GL, a data driver DD electrically connected to the data line DL, a timing controller TC electrically connected to the gate driver GD and the data driver DD and a power unit PU electrically connected to the power voltage supply line PL can be disposed outside the active area AA. At least one of the gate driver GD, the data driver DD, the timing controller TC and the power unit PU can be disposed on the bezel area BZ. For example, the display apparatus according to the embodiment of the present disclosure can be a GIP (Gate In Panel) type display apparatus in which the gate driver GD is formed on the bezel area BZ.

Align areas KA can be disposed on the bezel area BZ. Each of the align areas KA can be spaced apart from the active area AA. For example, in the display apparatus according to the embodiment of the present disclosure, each of the align areas KA can be disposed close to one of four corners of the display panel DP.

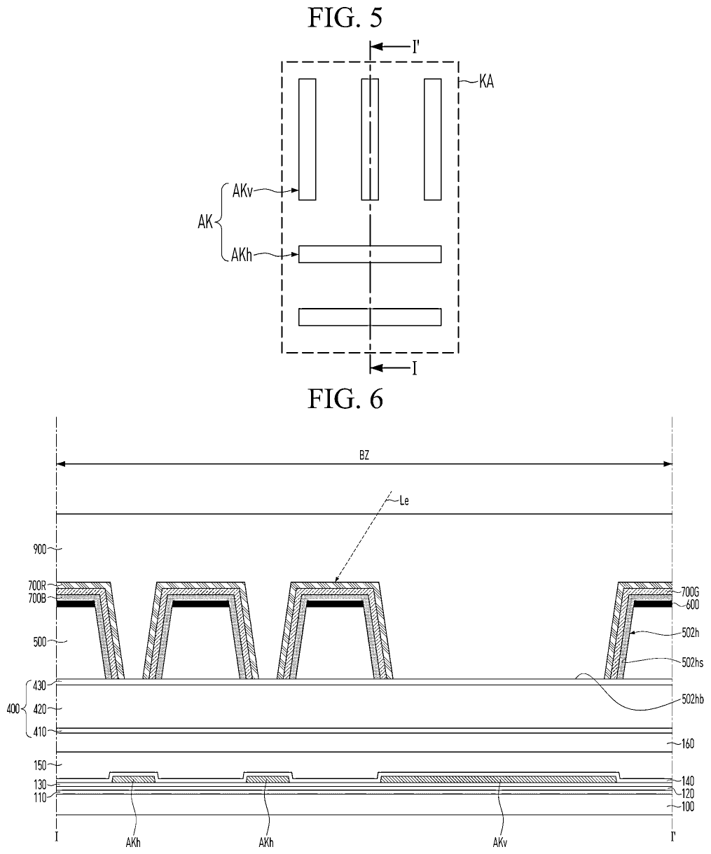

FIG. 5 is an enlarged view of an align area KA in FIG. 1. FIG. 6 is a view taken along line I-I′ of FIG. 5.

Referring to FIGS. 1, 3, 5 and 6, the display apparatus according to the embodiment of the present disclosure can include at least one alignment key AK disposed in each align area KA. The alignment key AK can be used to align the device substrate 100 within a process chamber. For example, a deposition equipment for a process of forming the planarization layer 150 can determine whether the device substrate 100 is misaligned within the deposition chamber by checking the position of the alignment key AK through vision. The alignment key AK can have various shapes. For example, the alignment key AK can include a plurality of first keys AKh having a bar shape extending in a first direction and a plurality of second keys AKv having a bar shape extending in a second direction perpendicular to the first direction. The plurality of first keys AKh can be disposed side by side in the second direction. The plurality of second keys AKv can be disposed side by side in the first direction. Thus, in the display apparatus according to the embodiment of the present disclosure, the misalignment of the device substrate 100 in the first direction and the second direction can be simultaneously checked by the alignment key AK.

The alignment key AK can include a material having a high reflectivity. The alignment key AK can be formed by using a process of forming the driving circuit DC of each pixel area PA. For example, the plurality of first keys AKh and the plurality of second keys AKv can include a same material as the second drain electrode 225 and the second source electrode 227 of each pixel area PA. The plurality of first keys AKh and the plurality of second keys AKv can be disposed on a same layer as the second drain electrode 225 and the second source electrode 227 of each pixel area PA. For example, the buffer insulating layer 110, the gate insulating layer 120, the interlayer insulating layer 130, the device passivation layer 140, the planarization layer 150, the bank insulating layer 160, the encapsulation structure 400, the optical insulating layer 500 and the lens passivation layer 900 can extend on the bezel area BZ, and the plurality of first keys AKh and the plurality of second keys AKv can be disposed between the interlayer insulating layer 130 and the device passivation layer 140 of the bezel area BZ. The plurality of first keys AKh and the plurality of second keys AKv can be formed by a same process as the second drain electrode 225 and the second source electrode 227 of each pixel area PA. For example, the plurality of first keys AKh and the plurality of second keys AKv can be formed simultaneously with the second drain electrode 225 and the second source electrode 227 of each pixel area PA.

The optical insulating layer 500 can include align grooves 502h overlapping with the alignment key AK. For example, each of the align grooves 502h can overlap one of the first keys AKh or one of the second keys AKv. A plane of each align groove 502h can have a shape corresponding to a plane of the corresponding first key AKh or a plane of the corresponding second key AKv. Thus, in the display apparatus according to the embodiment of the present disclosure, the alignment key AK can be effectively checked in an align process of the device substrate 100.

Each of the align groove 502h can include an align bottom surface 502hb and an align sidewall 502hs. The align bottom surface 502hb of each align groove 502h can be disposed close to the encapsulation structure 400. The align sidewall 502hs of each align groove 502h can extend from an edge of the align bottom surface 502hb of the corresponding align groove 502h. The align sidewall 502hs of each align groove 502h can be inclined with respect to the align bottom surface 502hb of the corresponding align groove 502h. For example, a horizontal width of each align groove 502h can increase toward the upper surface of the optical insulating layer 500.

The align grooves 502h can be formed simultaneously with the optical grooves 501h. For example, each of the align grooves 502h can completely penetrate the optical insulating layer 500. The align bottom surface 502hb of each align groove 502h can be continuous with the lower surface of the optical insulating layer 500. Thus, in the display apparatus according to the embodiment of the present disclosure, the decrease in the process efficiency due to a process of forming the align grooves 502h can be prevented.

The color filters 700B, 700G and 700R can be stacked on the align sidewall 502hs of each align groove 502h. For example, the blue color filter 700B, the green color filter 700G and the red color filter 700R can be stacked on the align sidewall 502hs of each align groove 502h. The align bottom surface 502hb of each align groove 502h can include a region disposed outside the color filters 700B, 700G and 700R. For example, a center region of the align bottom surface 502hb of each align groove 502h exposed by the color filters 700B, 700G and 700R can overlap one of the first keys AKh or one of the second keys AKv. The barrier pattern 600 can be disposed between the upper surface of the optical insulating layer 500 and the color filters 700B, 700G and 700R in the bezel area BZ. Thus, in the display apparatus according to the embodiment of the present disclosure, the reflection of the external light Le on the bezel area BZ can be prevented. Therefore, in the display apparatus according to the embodiment of the present disclosure, the visibility of the alignment key AK can be improved. For example, in the display apparatus according to the embodiment of the present disclosure, the reliability in a process of aligning the device substrate 100 within the process chamber can be improved.

The display apparatus according to the embodiment of the present disclosure is described that the driving circuit DC of each pixel area PA can consist of the first thin film transistor TR1, the second thin film transistor TR2 and the storage capacitor Cst. However, in the display apparatus according to another embodiment of the present disclosure, the driving circuit DC of each pixel area PA can include a driving thin film transistor and at least one switching thin film transistor. For example, in the display apparatus according to another embodiment of the present disclosure, the driving circuit DC of each pixel area PA can further include a third thin film transistor capable of initializing the storage capacitor Cst of the corresponding pixel area PA according to the gate signal. The third thin film transistor of each pixel area PA can include a third semiconductor pattern, a third gate electrode, a third drain electrode and a third source electrode. The third semiconductor pattern of each pixel area PA can include a semiconductor material. The third gate electrode of each pixel area PA can be electrically connected to the corresponding gate line GL. The third drain electrode of each pixel area PA can be electrically connected to an initial line applying an initial signal. The third source electrode of each pixel area PA can be electrically connected to the storage capacitor Cst of the corresponding pixel area PA. Thus, in the display apparatus according to another embodiment of the present disclosure, the degree of freedom in configuring each driving circuit DC can be improved.

In the display apparatus according to the embodiment of the present disclosure, the location and the electric connection of the first drain electrode, the first source electrode, the second drain electrodes 225 and the second source electrode 227 in each driving circuit DC can vary depending on the configuration of the corresponding driving circuit DC and/or the type of the corresponding thin film transistors TR1 and TR2. For example, in the display apparatus according to another embodiment of the present disclosure, the second gate electrode 223 of each driving circuit DC can be electrically connected to the first drain electrode of the corresponding driving circuit DC. Thus, in the display apparatus according to another embodiment of the present disclosure, the degree of freedom in the configuration of each driving circuit DC and the type of each thin film transistor TR1 and TR2 can be improved.

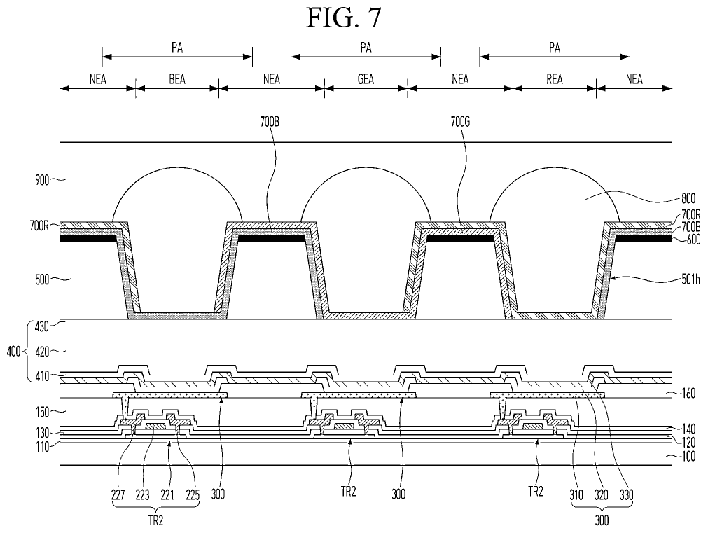

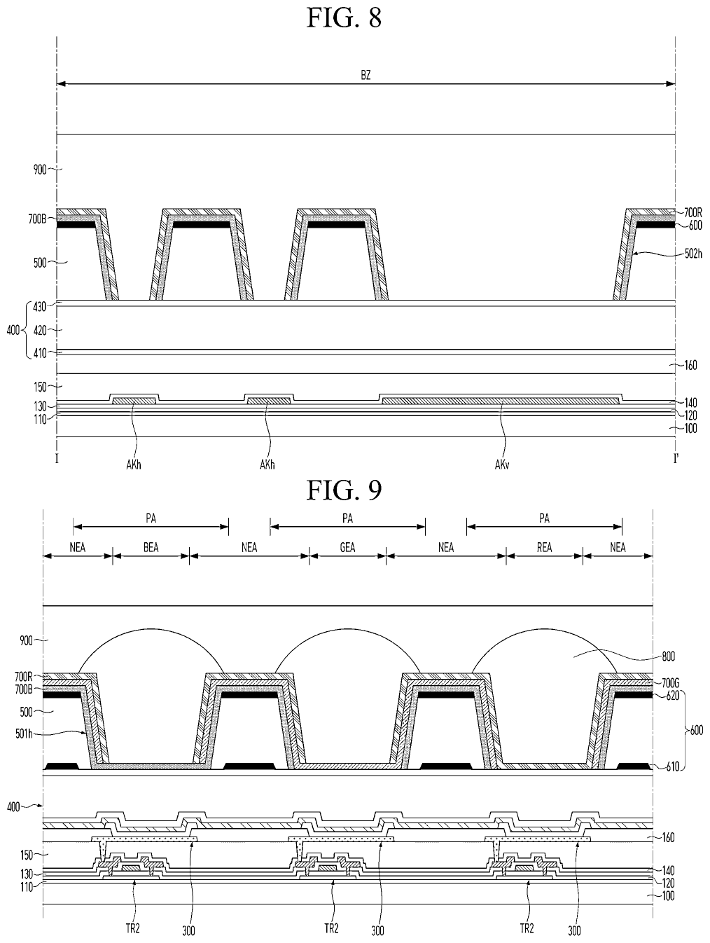

The display apparatus according to the embodiment of the present disclosure is described that the blue color filter 700B, the green color filter 700G and the red color filter 700R can be stacked on the optical sidewall 501hs of each optical groove 501h. However, in the display apparatus according to another embodiment of the present disclosure, the optical sidewall 501hs of each optical groove 501h can be covered by at least two color filters 700B, 700G and 700R including different materials. The color filter 700B, 700G and 700R overlapping with the emission area BEA, GEA and REA of each pixel area PA can extend onto the optical sidewall 501hs of the optical groove 501h disposed on the corresponding pixel area PA. For example, in the display apparatus according to the embodiment of the present disclosure, the blue color filter 700B can overlap the green color filter 700G or the red color filter 700R on the optical sidewall 501hs of the optical groove 501h disposed on the blue emission area BEA, the green color filter 700G can overlap the blue color filter 700B or the red color filter 700R on the optical sidewall 501hs of the optical groove 501h disposed on the green emission area GEA, and the red color filter 700R can overlap the blue color filter 700B or the green color filter 700G on the optical sidewall 501hs of the optical groove 501h disposed on the red emission area REA, as shown in FIGS. 7 and 8. The barrier pattern 600 can be covered by two color filters 700B, 700G and 700R including different materials. Thus, in the display apparatus according to another embodiment of the present disclosure, a process of forming the color filters 700B, 700G and 700R can be simplified. And, in the display apparatus according to another embodiment of the present disclosure, the deterioration in the color sense due to the misalignment of the color filters 700B, 700G and 700R can be prevented.

Two color filters 700B, 700G and 700R stacked on the align sidewall of each align groove 502h can be the same as two color filters 700B, 700G and 700R stacked on the align sidewall of adjacent align groove 502h. The wavelength range of the light passing through the primary color filter 700B, 700G and 700R disposed on the align sidewall of each align groove 502h can't overlap the wavelength range of the light passing through the secondary color filter 700B, 700G and 700R disposed on the align sidewall of each align groove 502h. For example, the blue color filter 700B and the red color filter 700R can be stacked on the align sidewall of each align groove 502h. Therefore, in the display apparatus according to another embodiment of the present disclosure, the visibility of the first keys AKh and the second keys AKv can be effectively improved.

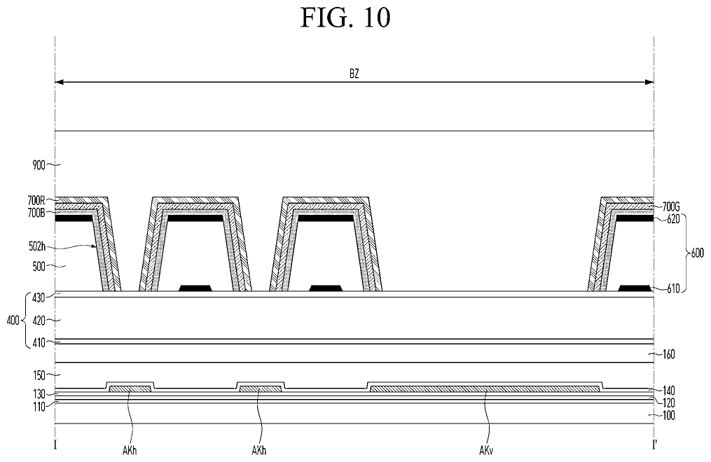

The display apparatus according to the embodiment of the present disclosure is described that the lower surface of the optical insulating layer 500 can be in direct contact with the upper surface of the encapsulation structure 400. However, in the display apparatus according to another embodiment of the present disclosure, at least one layer or pattern can be disposed between the encapsulation structure 400 and the optical insulating layer 500. For example, in the display apparatus according to another embodiment of the present disclosure, the barrier pattern 600 can include a lower barrier pattern 610 disposed between the encapsulation structure 400 and the optical insulating layer 500 and an upper barrier pattern 620 disposed on the upper surface of the optical insulating layer 500, as shown in FIGS. 9 and 10. The lower barrier pattern 610 can be spaced apart from the optical bottom surface and the optical sidewall of each optical groove 501h. For example, the lower barrier pattern 610 can be completely covered by the optical insulating layer 500. The lower barrier pattern 610 can include a material blocking light. For example, the lower barrier pattern 610 can include a black dye, such as carbon black. The lower barrier pattern 610 can include a same material as the upper barrier pattern 620. Thus, in the display apparatus according to another embodiment of the present disclosure, the travelling direction of the light emitted from the light-emitting device 300 of each pixel area PA can be restricted by the lower barrier pattern 610, the upper barrier pattern 620, the optical grooves 501h and the color filters 700B, 700G and 700R. For example, in the display apparatus according to the embodiment of the present disclosure, the light emitted from the light-emitting device 300 of each pixel area PA toward adjacent non-emission area NEA can be primarily blocked by the lower barrier pattern 610, secondarily blocked by the upper barrier pattern 620, and the progress of the light reflected by the lower barrier pattern 610 and/or the upper barrier pattern 620 can be blocked by the color filters 700B, 700G and 700R stacked on the optical sidewall of each optical groove 501h. Therefore, in the display apparatus according to another embodiment of the present disclosure, the narrow viewing angle can be effectively realized.

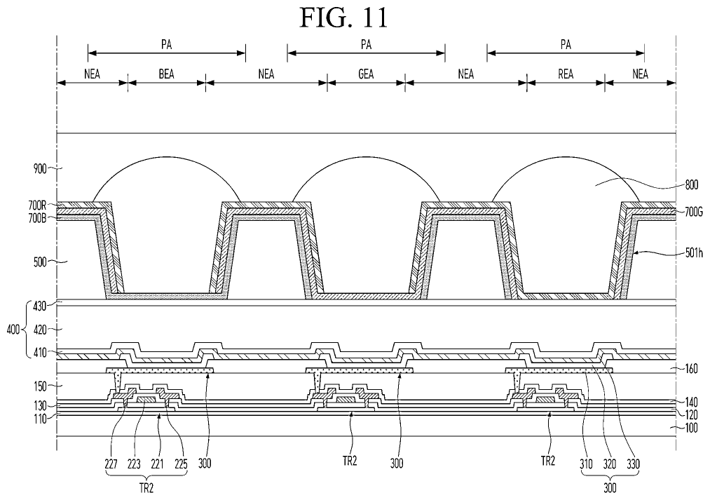

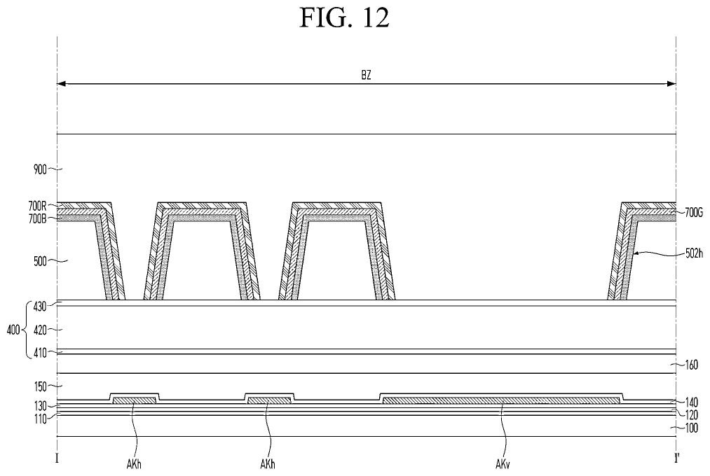

The display apparatus according to the embodiment of the present disclosure is described that the barrier pattern 600 can be covered by the color filters 700B, 700G and 700R. However, in the display apparatus according to another embodiment of the present disclosure, the barrier pattern 600 can be omitted. For example, in the display apparatus according to another embodiment of the present disclosure, the upper surface of the optical insulating layer 500 can be in direct contact with one of the color filters 700B, 700G and 700R, as shown in FIGS. 11 and 12. Thus, in the display apparatus according to another embodiment of the present disclosure, the light emitted from the light-emitting device 300 of each pixel area PA can be limited by the color filters 700B, 700G and 700R stacked on the upper surface of the optical insulating layer 500 and the optical sidewall of each optical groove 501h. For example, in the display apparatus according to another embodiment of the present disclosure, a process of forming the barrier pattern can be completely omitted. Therefore, in the display apparatus according to another embodiment of the present disclosure, the process of realizing the narrow viewing angle can be minimized. And, in the display apparatus according to another embodiment of the present disclosure, the production energy can be significantly reduced by process optimization.

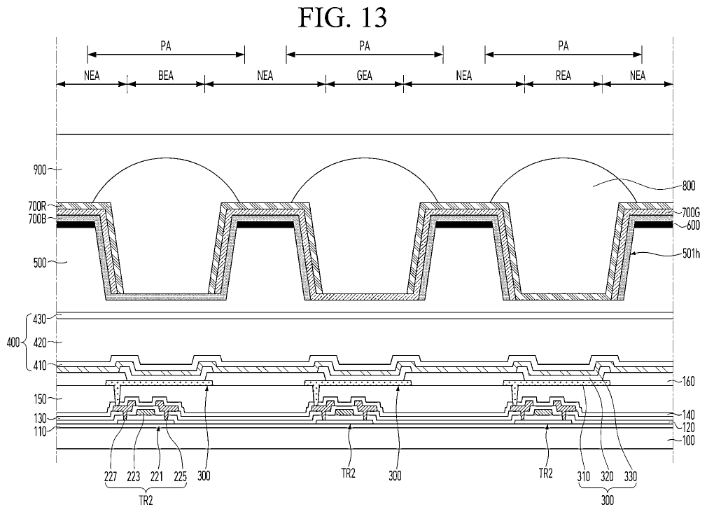

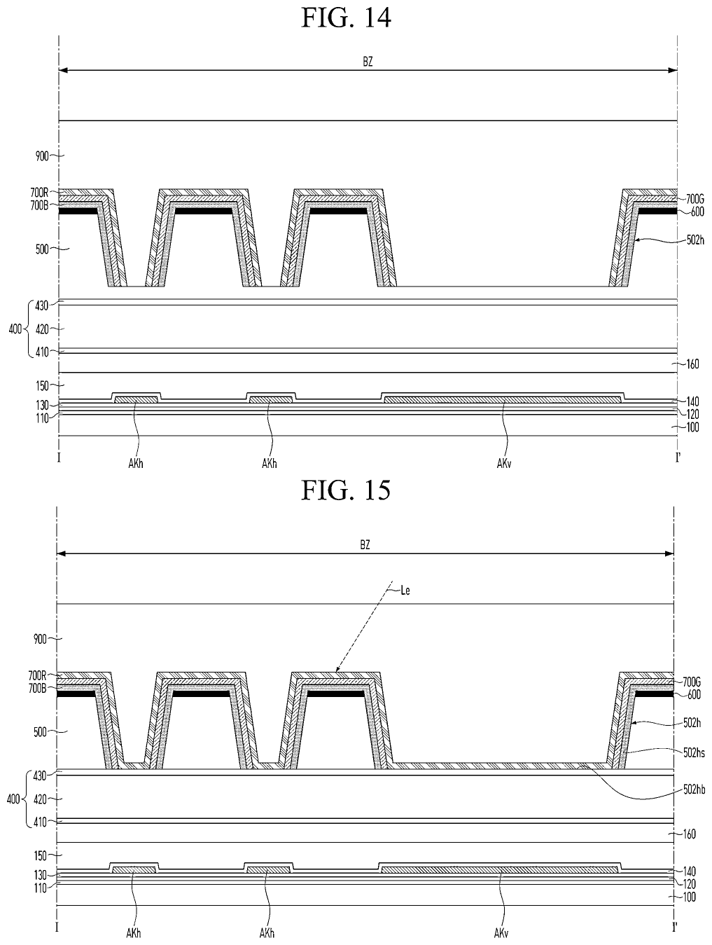

The display apparatus according to the embodiment of the present disclosure is described that the optical bottom surface 501hb of each optical groove 501h and the align bottom surface 502hb of each align groove 502h can be continuous with the lower surface of the optical insulating layer 500. However, in the display apparatus according to another embodiment of the present disclosure, the optical bottom surface 501hb of each optical groove 501h and the align bottom surface 502hb of each align groove 502h can be spaced apart from the encapsulation structure 400. For example, in the display apparatus according to another embodiment of the present disclosure, the optical insulating layer 500 can includes a region disposed between the encapsulation structure 400 and the optical bottom surface of each optical groove 501h and a region disposed between the encapsulation structure 400 and the align bottom surface of each align groove 502h, as shown in FIGS. 13 and 14. Thus, in the display apparatus according to another embodiment of the present disclosure, an optical path of the light emitted from the light-emitting device 300 of each pixel area PA can be increased by the optical insulating layer 500. For example, in the display apparatus according to another embodiment of the present disclosure, the optical path of the light emitted from the light-emitting device 300 of each pixel area PA can be sufficiency secured by the optical insulating layer 500. Therefore, in the display apparatus according to another embodiment of the present disclosure, the quality of the image recognized by the user can be improved.

The display apparatus according to the embodiment of the present disclosure is described that the color filters 700B, 700G and 700R can expose the center region of the align bottom surface 502hb of each align groove 502h. However, in the display apparatus according to another embodiment of the present disclosure, the align bottom surface 502hb of each align groove 502h can be covered by at least one of the color filters 700B, 700G and 700R. For example, in the display apparatus according to another embodiment of the present disclosure, the align bottom surface 502hb of each align groove 502h can be covered by the red color filter 700R, as shown in FIG. 15. Thus, in the display apparatus according to another embodiment of the present disclosure, the decrease in the visibility of the alignment key AKh and AKv due to the light reflected by the plurality of first keys AKh and the plurality of second keys AKv can be prevented. Thus, in the display apparatus according to another embodiment of the present disclosure, the process of aligning the device substrate 100 within the process chamber can be effectively performed.

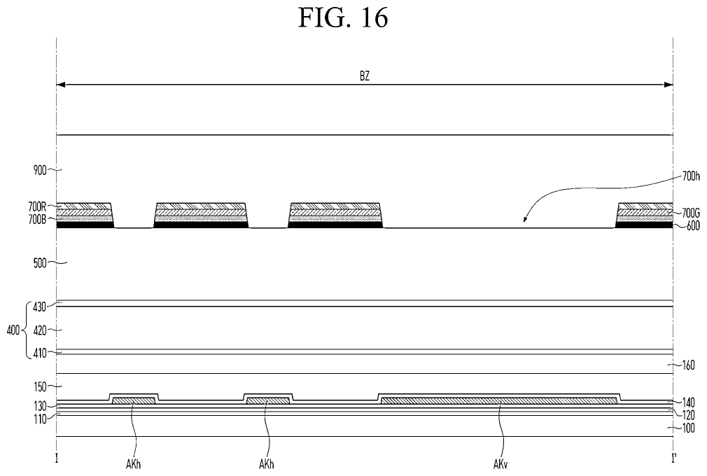

The display apparatus according to the embodiment of the present disclosure is described that the align grooves 502h can be formed in the optical insulating layer 500 of the bezel area BZ. However, in the display apparatus according to another embodiment of the present disclosure, the color filter 700B, 700G and 700R of the bezel area BZ can include an opening 700h exposing a portion of the upper surface of the optical insulating layer 500 overlapping with the plurality of first keys AKh and the plurality of second keys AKv, as shown in FIG. 16. For example, in the display apparatus according to another embodiment of the present disclosure, the align grooves can't be formed. The location of the alignment key AKh and AKv can be checked through the opening 700h penetrating the color filters 700B, 700G and 700R. Thus, in the display apparatus according to another embodiment of the present disclosure, the decrease in the visibility of the alignment key AKh and AKv due to the misalignment of the align grooves can be prevented.

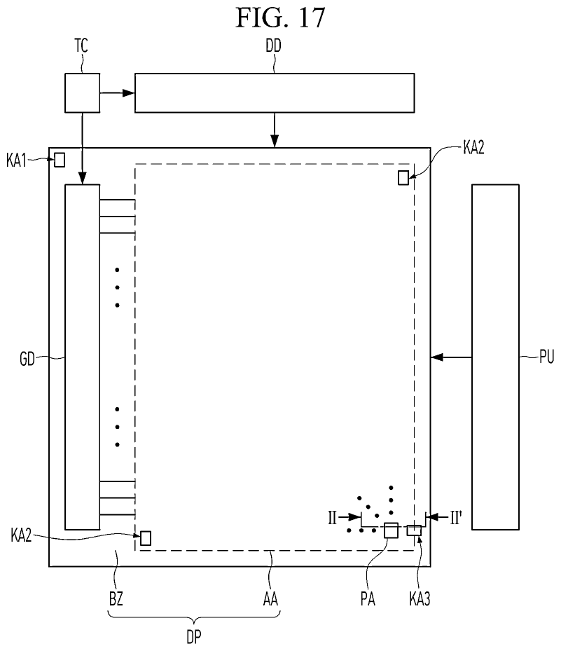

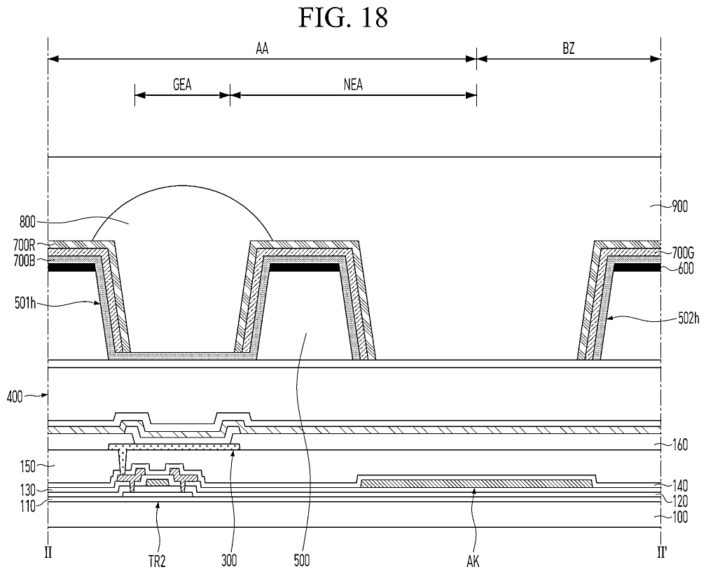

The display apparatus according to the embodiment of the present disclosure is described that the align areas KA can be disposed on the bezel area BZ. However, in the display apparatus according to another embodiment of the present disclosure, the align areas KA can be formed in various positions. For example, the display apparatus according to the embodiment of the present disclosure can include a first align area KA1 disposed on the bezel area BZ, a second align area KA2 disposed on the active area AA, and a third align area KA3 overlapping with a boundary between the active area AA and the bezel area BZ, as shown in FIGS. 17 and 18. The alignment key AK of each align area KA1, KA2 and KA3 can be spaced apart from the emission areas GEA, the gate driver GD and the signal wirings. For example, the alignment key AK and the align groove 502h overlapping with the alignment key AK in the third align area KA3 can include a region overlapping with the non-emission area NEA of the active area AA. For example, in the display apparatus according to another embodiment of the present disclosure, the alignment key AK and the align groove 502h can be disposed on the non-emission area NEA or the bezel area BZ spaced apart from the emission areas GEA, the gate driver GD and the signal wirings. Thus, in the display apparatus according to another embodiment of the present disclosure, the alignment of the device substrate 100 using the alignment key AK can be effectively performed.

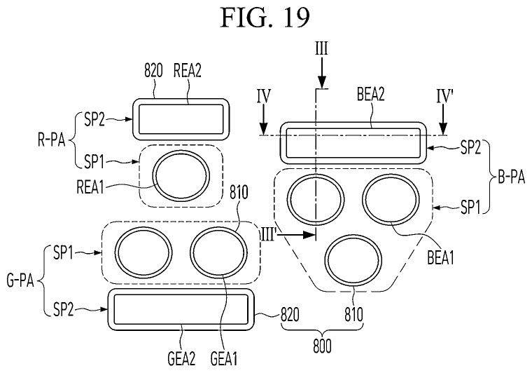

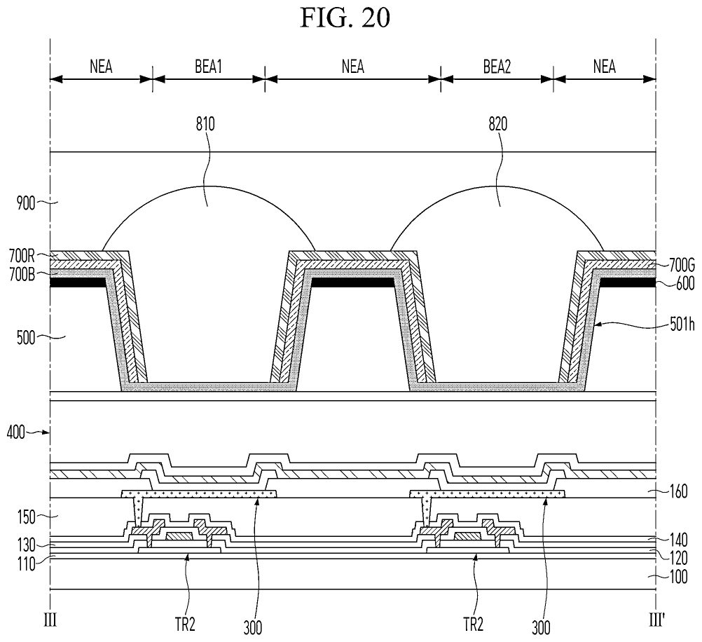

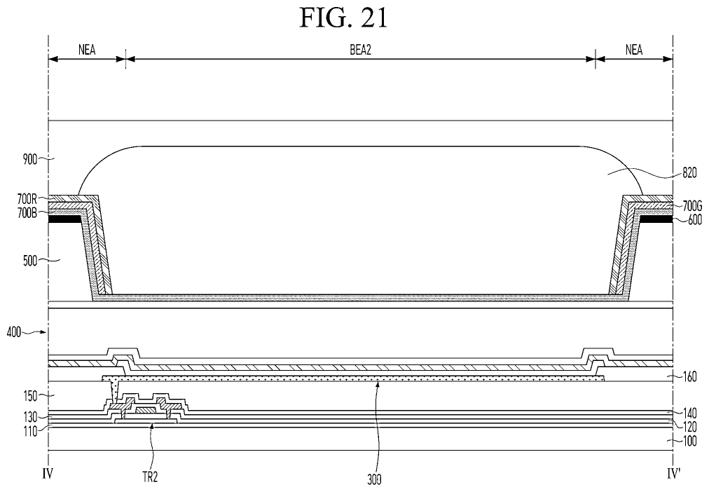

The display apparatus according to the embodiment of the present disclosure is described that a single emission area BEA, GEA and REA can be defined in each pixel area PA. However, in the display apparatus according to another embodiment of the present disclosure, each of the pixel areas PA can include a plurality of emission areas BEA, GEA and REA. For example, in the display apparatus according to another embodiment of the present disclosure, each of the pixel areas B-PA, G-PA and R-PA can include a first sub-pixel SP1 and a second sub-pixel SP2, each of the first sub-pixel SP1 and the second sub-pixel SP2 in each pixel area B-PA, G-PA and R-PA can include at least one emission area BEA1, BEA2, GEA1, GEA2, REA1 and REA2, as shown in FIGS. 19 to 21. The second sub-pixel SP2 of each pixel area B-PA, G-PA and R-PA can display a same color as the first sub-pixel SP1 of the corresponding pixel area B-PA, G-PA and R-PA. For example, each of the pixel areas B-PA, G-PA and R-PA can be one of the blue pixel area B-PA in which the first sub-pixel SP1 and the second sub-pixel SP2 realize a blue color, the green pixel area G-PA in which the first sub-pixel SP1 and the second sub-pixel SP2 realize a green color, and the red pixel area R-PA in which the first sub-pixel SP1 and the second sub-pixel SP2 realize a red color.

The number of the emission area BEA1, BEA2, GEA1, GEA2, REA1 and REA2 disposed in the second sub-pixel SP2 of each pixel area B-PA, G-PA and R-PA can be different from the number of the emission area BEA1, BEA2, GEA1, GEA2, REA1 and REA2 disposed in the first sub-pixel SP1 of the corresponding pixel area B-PA, G-PA and R-PA. For example, three first blue emission areas BEA1 can be defined in the first sub-pixel SP1 of the blue pixel area B-PA, and a single second blue emission area BEA2 can be defined in the second sub-pixel SP2 of the blue pixel area B-PA. Two first green emission areas GEA1 can be defined in the first sub-pixel SP1 of the green pixel area B-PA, and a single second green emission area GEA2 can be defined in the second sub-pixel SP2 of the green pixel area G-PA. A single first red emission area REA1 can be defined in the first sub-pixel SP1 of the red pixel area R-PA, and a single second red emission area REA2 can be defined in the second sub-pixel SP2 of the red pixel area R-PA.

The first sub-pixel SP1 and the second sub-pixel SP2 of each pixel area B-PA, G-PA and R-PA can be selectively operated. For example, the first sub-pixel SP1 of each pixel area B-PA, G-PA and R-PA can be operated simultaneously with the first sub-pixels SP1 of adjacent pixel areas B-PA, G-PA and R-PA, and the second sub-pixel SP2 of each pixel area B-PA, G-PA and R-PA can be operated simultaneously with the second sub-pixels SP2 of adjacent pixel areas B-PA, G-PA and R-PA. The second sub-pixel SP2 of each pixel area B-PA, G-PA and R-PA can have a viewing angle different from the first sub-pixel SP1 of each pixel area B-PA, G-PA and R-PA. For example, the second emission area BEA2, GEA2 and REA2 defined in the second sub-pixel SP2 of each pixel area B-PA, G-PA and R-PA can have a planar shape different from the first emission area BEA1, GEA1 and REA1 defined in the first sub-pixel SP1 of the corresponding pixel area B-PA, G-PA and R-PA. A plane of the second emission area BEA2, GEA2 and REA2 defined in each pixel area B-PA, G-PA and R-PA can have a circle shape, and a plane of the first emission area BEA1, GEA1 and REA1 defined in each pixel area B-PA, G-PA and R-PA can have a bar shape extending in a first direction. Thus, in the display apparatus according to another embodiment of the present disclosure, the second sub-pixel SP2 of each pixel area B-PA, G-PA and R-PA can have a viewing angle wider than the first sub-pixel SP1 of the corresponding pixel area B-PA, G-PA and R-PA in the first direction. For example, in the display apparatus according to another embodiment of the present disclosure, the image realized by the first sub-pixel SP1 of each pixel area B-PA, G-PA and R-PA can't be recognized by the people around the user, and the image realized by the second sub-pixel SP2 of each pixel area B-PA, G-PA and R-PA can be shared by the user and the people located side by side with the user in the first direction. Therefore, in the display apparatus according to another embodiment of the present disclosure, the image of a narrow viewing angle mode and the image of a wide viewing angle mode can be selectively provided by the first sub-pixel SP1 and the second sub-pixel SP2 of each pixel area B-PA, G-PA and R-PA.

The pixel lens 800 can include first pixel lenses 810 disposed on the first emission area BEA1, GEA1 and REA1 of each pixel area B-PA, G-PA and R-PA and second pixel lenses 820 disposed on the second emission area BEA2, GEA2 and REA2 of each pixel area PA. Each of the first pixel lenses 810 can have a shape corresponding to the corresponding first emission area BEA1, GEA1 and REA1, and each of the second pixel lenses 820 can have a shape corresponding to the corresponding second emission area BEA2, GEA2 and REA2. For example, a plane of each first pixel lens 810 can have a circle shape, and a plane of each second pixel lens 820 can have a bar shape. Each of the first pixel lenses 810 and each of the second pixel lenses 820 can include a region disposed inside one of the optical grooves 501h. For example, a portion of each first pixel lens 810 and a portion of each second pixel lens 820 disposed inside the corresponding optical groove 501h can be surrounded by the color filters 700B, 700G and 700G stacked on the optical sidewall of each optical groove 501h. Thus, in the display apparatus according to another embodiment of the present disclosure, the travelling direction of the light emitted through the emission area BEA1, BEA2, GEA1, GEA2, REA1 and REA2 of each sub-pixel SP1 and SP2 can be effectively restricted, and the deterioration of the image due to the light leakage and the reflection of the external light can be prevented. Therefore, in the display apparatus according to another embodiment of the present disclosure, the degree of freedom for the configuration and the planar shape of each pixel area B-PA, G-PA and R-PA can be improved.

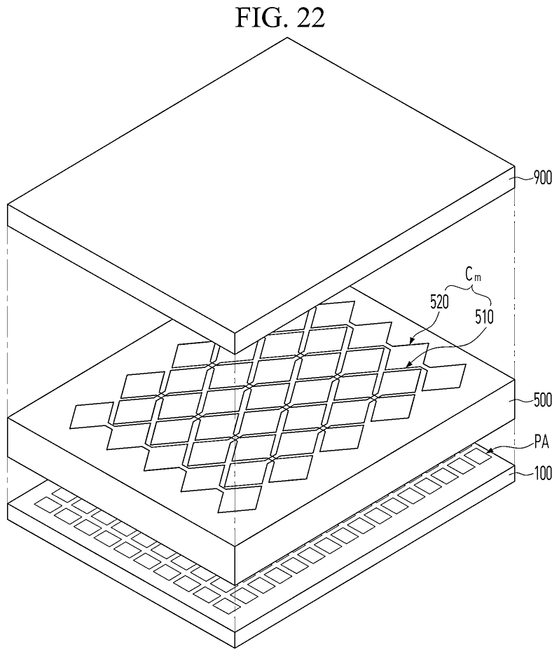

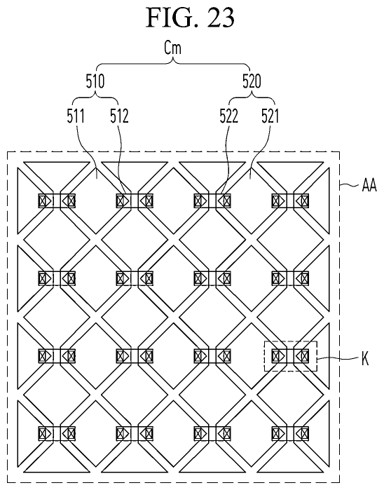

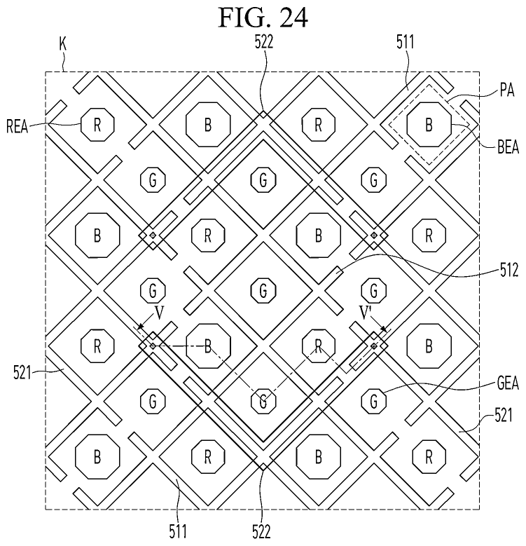

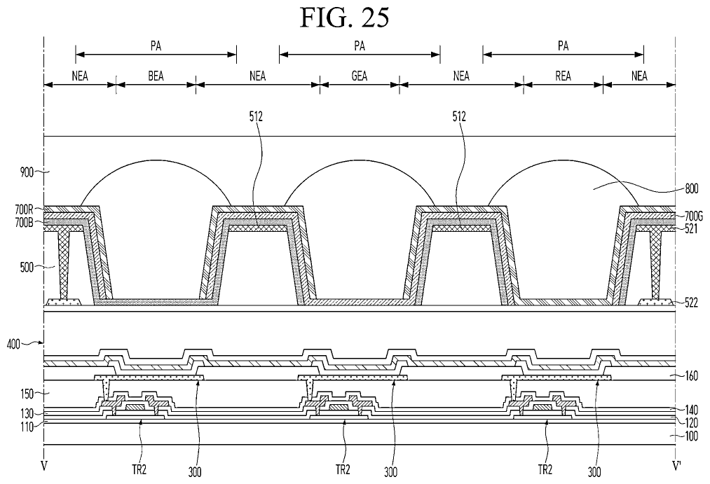

The display apparatus according to the embodiment of the present disclosure is described that the barrier pattern 600 can include a black dye. However, in the display apparatus according to another embodiment of the present disclosure, the barrier pattern 600 can include a conductive material. For example, in the display apparatus according to another embodiment of the present disclosure, a touch sensor Cm can be disposed between the encapsulation structure 400 and the lens passivation layer 900, as shown in FIGS. 22 to 25. The touch sensor Cm can sense a touch of the user and/or a tool. For example, the touch sensor Cm can detect presence or absence of the touch and the touch position of the user and/or the tool using the change of a mutual capacitance. The touch sensor Cm can include driving touch lines 510 in which a touch driving signal is applied, and sensing touch lines 520 in which a touch sensing signal is applied.

Each of the driving touch lines 510 can include first touch electrodes 511 and first bridge electrodes 512. The first bridge electrodes 512 can electrically connect between the first touch electrodes 511. For example, each of the driving touch lines 510 can include the first touch electrodes 511 connected in a first direction by the first bride electrodes 512. Each of the sensing touch lines 520 can include second touch electrodes 521 and second bridge electrodes 522. The second touch electrodes 521 can be disposed between the first touch electrodes 511. For example, the first touch electrodes 511 and the second touch electrodes 512 can be arranged to stagger each other. Thus, in the display apparatus according to another embodiment of the present disclosure, the touch of the user and/or the tool can be sensed by using the driving touch lines 510 and the sensing touch lines 520.

The second bridge electrodes 522 can electrically connect between the second touch electrodes 521. The second touch electrodes 521 can be connected in a second direction different from the first direction. For example, the second touch electrodes 521 can be connected by the second bridge electrodes 522 in a direction perpendicular to the first touch electrodes 511. Each of the sensing touch lines 520 can intersect one of the driving touch lines 510. Each of the second bridge electrodes 522 can intersect one of the first bridge electrodes 512. The second bridge electrodes 522 can be disposed on a different layer from the first bridge electrodes 512. For example, the second bridge electrodes 522 can be disposed between the encapsulation structure 400 and the optical insulating layer 500, and the first touch electrodes 511, the second touch electrodes 521 and the first bridge electrodes 512 can be disposed the upper surface of the optical insulating layer 500.

The first touch electrodes 511, the first bridge electrodes 512, the second touch electrodes 521 and the second bridge electrodes 522 can include a material having a relative low resistance. For example, the first touch electrodes 511, the first bridge electrodes 512, the second touch electrodes 521 and the second bridge electrodes 522 can include a metal, such as copper (Cu), molybdenum (Mo), titanium (Ti) and Tantalum (Ta). The first touch electrodes 511, the first bridge electrodes 512, the second touch electrodes 521 and the second bridge electrodes 522 can be covered by the stacked color filters 700B, 700G and 700R. Thus, in the display apparatus according to another embodiment of the present disclosure, the reflection of the external light due to the first touch electrodes 511, the first bridge electrodes 512, the second touch electrodes 521 and the second bridge electrodes 522 can be prevented. For example, in the display apparatus according to another embodiment of the present disclosure, the reflection of the external light due to the touch sensor Cm can be prevented. Therefore, in the display apparatus according to another embodiment of the present disclosure, the quality of the image can be improved, without the decrease of the touch sensitivity using the touch sensor Cm.

The touch sensor Cm can be disposed within the active area AA. The first touch electrodes 511, the first bridge electrodes 512, the second touch electrodes 521 and the second bridge electrodes 522 can be disposed outside the emission area BEA, GEA and REA defined in each pixel area PA. For example, the first touch electrodes 511, the first bridge electrodes 512, the second touch electrodes 521 and the second bridge electrodes 522 can overlap the bank insulating layer 160. Thus, in the display apparatus according to another embodiment of the present disclosure, the light emitted from the light-emitting device 300 of each pixel area PA toward adjacent optical insulating layer 500 can be blocked by the first touch electrodes 511, the first bridge electrodes 512, the second touch electrodes 521 and the second bridge electrodes 522. For example, in the display apparatus according to another embodiment of the present disclosure, the travelling direction of the light emitted from the light-emitting device 300 of each pixel area PA can be limited by the touch sensor Cm. For example, the second bridge electrodes 522 disposed between the encapsulation structure 400 and the optical insulating layer 500 can function as a lower barrier pattern, and the first touch electrodes 511, the first bridge electrodes 512 and the second touch electrodes 521 disposed on the upper surface of the optical insulating layer 500 can function as an upper barrier pattern. Therefore, in the display apparatus according to another embodiment of the present disclosure, a process of restricting the travelling direction of the light emitted from the light-emitting device 300 of each pixel area PA can be simplified. And, in the display apparatus according to another embodiment of the present disclosure, the deterioration of the image due to the light leakage and the reflection of the external light can be prevented and the production energy can be reduced by process optimization, without the decrease in the sensitivity of the touch detection using the touch sensor Cm.

As a result, the display apparatus according to the embodiments of the present disclosure can comprise the optical insulating layer and the color filters disposed on the light-emitting devices, wherein the optical insulating layer can include the optical grooves overlapping with the emission areas, wherein the optical bottom surface of each optical groove can be covered by the one of the color filters, and wherein at least two color filters can be stacked on the optical sidewall of each optical groove. Thus, in the display apparatus according to the embodiments of the present disclosure, the color mixing and the reflection of the external light can be prevented by the stacked color filters. Thereby, in the display apparatus according to the embodiments of the present disclosure, the quality of the image recognized by the user can be improved. Further, in the display apparatus according to the embodiments of the present disclosure, the production energy can be reduced by process optimization.

The present disclosure being thus described, it will be obvious that the same may be varied in many ways. Such variations are not to be regarded as a departure from the spirit and scope of the present disclosure, and all such modifications as would be obvious to one skilled in the art are intended to be included within the scope of the following claims.

What is claimed is:

1. A display apparatus comprising:
a first light-emitting device disposed on a first emission area of a device substrate;
an optical insulating layer disposed on the first light-emitting device, the optical insulating layer including a first optical groove overlapping with the first emission area;
a first color filer disposed on a first bottom surface of the first optical groove, the first color filter extending onto a first sidewall of the first optical groove; and
a second color filter including a different material from the first color filter, the second color filter overlapping with the first color filter on the first sidewall of the first optical groove,
wherein the first bottom surface of the first optical groove includes a region that does not overlap with the second color filter.

2. The display apparatus according to claim 1, wherein a light passing through the second color filer displays a different color from a light passing through the first color filter.

3. The display apparatus according to claim 1, wherein the first bottom surface of the first optical groove has a greater size than the first emission area.

4. The display apparatus according to claim 1, further comprising a pixel lens disposed on the optical insulating layer,
wherein the pixel lens overlaps the first emission area, and
wherein the pixel lens includes a region disposed inside the first optical groove.

5. The display apparatus according to claim 4, wherein a surface of the pixel lens opposite to the optical insulating layer has a convex shape.

6. The display apparatus according to claim 1, further comprising a second light-emitting device disposed between a second emission area of the device substrate and the optical insulating layer,
wherein the optical insulating layer includes a second optical groove overlapping with the second emission area,
wherein the second optical groove is spaced apart from the first optical groove,
wherein the first color filer and the second color filter are stacked on a second sidewall of the second optical groove, and
wherein a second bottom surface of the second optical groove includes a region that does not overlap with the first color filter.

7. The display apparatus according to claim 6, wherein the second color filter extends onto the second bottom surface of the second optical groove.

8. The display apparatus according to claim 1, wherein the first color filter and the second color filter extend onto an upper surface of the optical insulating layer opposite to the device substrate.

9. The display apparatus according to claim 8, further comprising an encapsulation structure disposed between the first light-emitting device and the optical insulating layer, and a lower barrier pattern disposed between the encapsulation structure and the optical insulating layer.

10. The display apparatus according to claim 9, further comprising an upper barrier pattern disposed on the upper surface of the optical insulating layer,
wherein the upper barrier pattern is covered by the first color filter and the second color filter.

11. The display apparatus according to claim 8, further comprising an align key disposed between the device substrate and the optical insulating layer,
wherein the align key is spaced apart from the first emission area, and
wherein at least one of the first color filter and the second color filter includes an opening corresponding to the align key.

12. The display apparatus according to claim 1, further comprising an encapsulation structure disposed between the first light-emitting device and the optical insulating layer,
wherein the optical insulating layer includes a region disposed between the encapsulation structure and the first bottom surface of the first optical groove.

13. A display apparatus comprising:
light-emitting devices disposed on emission areas of a device substrate;
an encapsulation structure disposed on the device substrate, the encapsulation structure covering the light-emitting devices;
an optical insulating layer disposed on the encapsulation structure, the optical insulating layer including optical grooves exposing a portion of the encapsulation structure that overlaps with the emission areas; and
color filters stacked on the optical insulating layer, the color filters extending onto a sidewall of each of the optical grooves,
wherein a light emitted from each of the emission areas displays a different color from a light emitted from an adjacent emission area, and
wherein a center area of a bottom surface of each of the optical grooves is covered by one of the color filters.

14. The display apparatus according to claim 13, wherein the one of the color filters disposed on the center area of the bottom surface of each of the optical grooves includes a different material from one of the color filters disposed on a center area of a bottom surface of the adjacent optical groove.

15. The display apparatus according to claim 13, further comprising an align key disposed between the device substrate and the encapsulation structure,
wherein the align key is spaced apart from the emission areas,
wherein the optical insulating layer includes an align groove spaced apart from the optical grooves,
wherein the align groove overlaps with the align key, and
wherein at least two of the color filters extend onto a sidewall of the align groove.

16. The display apparatus according to claim 15, wherein at least a portion of a bottom surface of the align groove is exposed by the color filters.

17. The display apparatus according to claim 15, wherein the device substrate includes an active area having the emission areas disposed therein and a bezel area disposed outside the active area, and
wherein the align key is disposed between the bezel area of the device substrate and the encapsulation structure.
